(19) United States
(12) Patent Application Publication
(10) Pub. No.: US 2026/0336397 A1
(43) Pub. Date: Oct. 29, 2026

(54) OPERATING DEVICE FOR A VEHICLE

(71) Applicant: BHTC GmbH, Lippstadt (DE)

(72) Inventors: Robin WOLF, Paderborn (DE); Pyry VÄLIMÄKI, Tampere (FI); Pasi KEMPPINEN, Tampere (FI); Bastian BANDLOW, Paderborn (DE)

(21) Appl. No.: 19/107,794

(22) PCT Filed: Sep. 5, 2023
(86) PCT No.: PCT/EP2023/074257

§ 371 Date: Feb. 28, 2025

(30) Foreign Application Priority Data
Sep. 6, 2022 (DE) 10 2022 122 571.2

(51) Int. Cl. B60K 35/10; B60K 35/50; H01H 3/38; H01H 13/04; H01H 13/14; H01H 13/20

(52) U.S. Cl. CPC B60K 35/10; B60K 35/50; H01H 3/38; H01H 13/04; H01H 13/14; H01H 13/20; B60K 2360/34

(57) ABSTRACT

The invention relates to operating device for vehicle comprising a housing having a front side with a recess extending between two opposing support edge portions on the front side of the housing, and having an elastic and/or directly or indirectly elastically mounted operating panel comprising two opposite support ends for support on the two support edge portions, on which the operating panel is attached to the housing, and covering the recess. The operating panel comprises a touch sensor system and a lower side facing the recess as well as an upper side facing away from the recess with an operating interface having several operating fields for manual actuation of the operating panel for the purpose of entering commands by pressing against the operating panel with a minimum pressing force on the operating fields. In addition, the operating device is provided with an actuation sensor for detecting a deflection of the operating panel during its manual actuation and a motion transmission element for transmitting the movement of the operating panel during its deflection to the actuation sensor. Furthermore, the operating device comprises an actuator for active haptic feedback.

The invention relates to an operating device for a vehicle and, in particular, to an operating device with an elongated, strip-shaped, closed operating interface with operating fields arranged next to one another, which can be pressed manually with a finger or an object in order to trigger the function associated with the operating field.

Operating concepts for vehicles with so-called “closed” operating interfaces are becoming increasingly popular. Such closed operating interfaces ensure protection against moisture potentially penetrating into the operating device and are also characterized by the fact that a separate switch does not have to be assigned to each operating field, as is the case, for example, with the arrangement of individual operating buttons (see, for example, WO-A-2019/215177, DE-B- 10 2016 002 021 and KR-B-10 187 478).

The detection of a valid actuation of an operating interface with several operating fields requires that, regardless of which of the operating fields is touched and thus at which location on the operating interface it is pressed against, the entire operating surface experiences a minimum pressing force that is detected either directly or as a minimum distance “covered” by the operating interface. If the operating interface is made of a comparatively stiff or rigid material, such as a relatively thick pane of glass, this requirement can be met with a comparatively simple design, even if there is only a single actuation sensor for detecting the application of the minimum pressing force. Said actuation sensor should then be arranged in a central position in relation to the operating interface. Operating concepts with linearly guided operating elements are also known, the operating interfaces of which maintain their parallel alignment when actuated.

Due to greater design freedom with regard to the geometric design of the operating interfaces of operating devices, there is an increasing trend towards manufacturing the operating elements that form the operating interfaces from plastic. However, plastic is less rigid and noticeably flexible, making it difficult to assign a single actuation sensor to an elongated, e.g. narrow, plastic operating interface with several adjacent operating fields, which is equally reliable in mechanically signaling a valid actuation of the operating interface regardless of which operating field the operating interface is actuated on. In contrast to rigid operating elements or interfaces, which displace virtually parallel or tilt when being pressed down, plastic operating elements or interfaces can bend when force is applied.

Furthermore, the plastic material can also cause problems with active haptic feedback, so that care should also be taken in this respect to ensure that the mechanical pulse-or vibration-excitation of the operating element behaves in the same way regardless of which operating field is currently being pressed down.

An object of the invention is to provide an improved operating device for a vehicle in this respect, which is characterized by a simple structure using the smallest possible number of components for parallel guidance of the operating element both during pressing down and during mechanical excitation for the active haptic feedback.

The object of the present invention is achieved with the invention proposing an operating device for a vehicle, provided with
a housing having a front side with a recess extending between two opposing support edge portions on the front side of the housing,
an elastic and/or directly or indirectly elastically mounted operating panel comprising two opposite support ends for support on the two support edge portions, on which the operating panel is mounted and/or attached to the housing, and covering the recess,
wherein the operating panel is adapted to be reversibly pressed down from a rest position into an actuation position and has an operating surface with operating fields,
a position detection sensor system for detecting the operating field of the operating surface of the operating panel which is contacted manually or by an object when being pressed down,
a return leaf spring arranged in the housing to support the movement of the depressed operating panel back to its rest position,
at least one actuation sensor for detecting when the operating panel assumes the actuation position,
at least one motion transmission element for transmitting the depression movement of the operating panel into a deflection of the return leaf spring,
wherein the at least one motion transmission element is arranged between the operating panel and the return leaf spring and has two opposite, rectilinear end portions, of which the first end portion is connected to the operating panel and the opposite second end portion is connected to the return leaf spring,
a control and evaluation unit (typically configured with, among other things, a microcontroller, I/O ports, ADC, DAC, memory and signal and/or data processing processor), which receives signals from the position detection sensor system and the at least one actuation sensor and, when a valid actuation of the operating panel is detected by transferring the operating panel into its actuation position by touching an operating field of the operating surface, outputs an output signal for further processing thereof to trigger an action associated with the relevant operating field, and
an actuator for pulse-or vibration-like excitation of the operating panel when the latter is validly actuated,
wherein the actuator is adapted to be controlled by an output signal emitted by the control and evaluation unit when a valid actuation is detected, and
wherein the actuator interacts with or acts on the return leaf spring to move the latter in order to excite the operating panel in a pulse-or vibration-like manner.

The operating device according to the invention comprises a housing on the front side of which there is an elastic and/or (directly or indirectly) elastically mounted operating panel. The operating panel has two opposite support ends on which it is attached to abut on the housing. So that the operating panel can bend easily when manual pressure is exerted, the front side of the housing has a recess in the form of a depression or indentation or in the form of an opening that is set back from at least parts of its border, so that the operating panel is adapted to be bent at least slightly when manually operated. While the lower side of the operating panel faces the recess in the housing, the operating interface of the operating device is located on its upper side, which has several typically adjacent operating fields for manual actuation for the purpose of entering commands by pressing against the operating panel with a minimum pressing force on the operating fields.

The deflection of the operating panel is detected by an actuation sensor. However, this is not done directly, but by means of the movement of at least one motion transmission element (for reasons of simplicity, the term “the motion transmission element” is used in the following, which means that its properties and installation and mounting environment also apply to every other motion transmission element, wherein two motion transmission elements appear to be suitable for this purpose), which in turn is rigidly connected to the operating panel. The motion transmission element has a rectilinear mounting edge portion that extends parallel to the longitudinal extension of the operating panel and is located approximately in the central area of the operating panel. If the operating panel is now actuated by pressing against the operating panel on one of the operating fields, the motion transmission element is displaced downwards in line with the deflection, even if the operating panel is actuated relatively close to its support ends. The motion transmission element interacts with a (preferably) single actuation sensor, which can operate optically, capacitively, resistively or inductively.

The stiffening of the operating panel in the area of the coupling thereto by the motion transmission element ensures that the motion transmission element experiences a minimum deflection, which is detected by the actuation sensor, regardless of where on the operating panel it is pressed against with a minimum pressing force, whereby a valid actuation of the operating device can be detected. To confirm that an operation of the operating panel is valid, the operating panel must also be touched on an operating field of its operating interface when it is pressed against the operating panel, which is done by a touch sensor system assigned to the operating interface that can work capacitively, optically, resistively or inductively.

The motion transmission element is a component that is resistant to forces acting substantially normal to the support plate and is resistant to shear forces. The actuation sensor detects a position offset of the motion transmission element when pressure is applied against the operating panel.

The operating device according to the invention also comprises an actuator for pulse-or vibration-like excitation of the operating panel when the latter is validly actuated. The actuator is controlled by an output signal emitted by the control and evaluation unit when a valid actuation is detected. According to the invention, the actuator for the pulse-or vibration-like excitation of the operating panel acts on the return leaf spring, i.e. mechanically excites this return leaf spring, the mechanical excitation of which is transmitted by the motion transmission element into a pulse-or vibration-like movement of the operating panel. Thus, it is provided according to the invention that the operating panel for the active haptic feedback is not directly mechanically excited, but indirectly, namely by means of its return spring, i.e. by means of its elastic mounting. The motion transmission element therefore advantageously serves to even out the movement of the operating panel both when it is pressed down and during active haptic feedback.

In an advantageous configuration of the invention, it can be provided that the actuator is configured as a tie rod magnet with a stator mounted in the housing and provided with a coil, and with a ferromagnetic armature, and that the armature is connected to the return leaf spring for pulse-or vibration-like excitation of the latter. In this exemplary embodiment, the actuator is therefore designed as a tie rod magnet and comprises its “own” ferromagnetic armature, which is attracted or repelled by the magnetic flux generated by the coil in the stator. In this exemplary embodiment, the ferromagnetic armature is firmly connected to the return leaf spring. Alternatively, the actuator can be configured as a tie rod magnet with a ferromagnetic armature attached in the housing and a stator provided with a coil, and the stator can be connected to the return leaf spring for pulse-or vibration-like excitation of the latter. In this exemplary embodiment, it is therefore the stator that is firmly connected to the return leaf spring. This is therefore a reversal of the tie rod magnet concept according to the previous exemplary embodiment.

In a further variant, the actuator can be a tie rod magnet with a stator mounted in the housing and provided with a coil, and with a ferromagnetic armature, wherein the return leaf spring forms the ferromagnetic armature of the tie rod magnet for pulse-or vibration-like excitation. This reduces the number of components for active haptic feedback.

In a further variant for the configuration of the actuator, the latter is configured as a plunger coil actuator, which has a base plate attached inside the housing, on which a stator coil is located, a spring-elastic actuator element mounted on the base plate and arranged at a distance from the base plate, and a permanent magnet element arranged on the actuator element and at least partially immersed in the stator coil, wherein the actuator element is connected to the return leaf spring for pulse-or vibration-like excitation of the latter.

In an alternative configuration of the actuator as a plunger coil actuator, the latter has a base plate attached inside the housing, on which or to which a coil is mounted, and a permanent magnet element at least partially immersed in the coil, wherein the permanent magnet element is connected to the return leaf spring for pulse-or vibration-like excitation. Here too, the number of components for active haptic feedback is reduced.

Preferably, in the case of the two configurations of the actuator as a plunger coil actuator, the base plate is a printed circuit board on which the coil is attached, for example by adhesion or by mechanical fastening means and preferably by soldering material.

Alternatively, one or more piezoelectric elements can also be used as an actuator, which are plate-shaped or strip-shaped and have two main surfaces and two connection elements or connections, wherein the at least one piezoelectric element contracts or expands when an electrical voltage is applied to the connection elements, depending on the polarity, wherein the at least one piezoelectric element abuts with one of its main surfaces against the return leaf spring for pulse-or vibration-like excitation and is rigidly connected to the latter, so that a shear-resistant connection is provided between the piezoelectric element(s) and the return leaf spring.

The other previous configurations for active haptic feedback are based on controlling the actuator without realizing a feedback, i.e. a control of the pulse-or vibration-like movement. In an advantageous embodiment of the invention with regard to control, it may be provided that the control and evaluation unit comprises a controller for controlling the deflection of the operating panel in the event of pulse-or vibration-like excitation thereof as a result of activation of the actuator, wherein the controller receives at its input a differential signal from a signal representing a target deflection of the operating panel and a signal representing the current extent of the deflection of the operating panel during the pulse-or vibration-like excitation and outputs at its output a control signal for the actuator for controlling the deflection of the operating panel in accordance with the target deflection.

The return leaf spring of the operating unit according to the invention can be attached inside the housing on one or both ends. In both cases, the motion transmission element is firmly connected to the return leaf spring in the area between the first end and the second end of the return leaf spring. If the actuator is configured as a piezoelectric element, this element is located between the first end of the return leaf spring attached to the housing, when the return leaf spring is attached to one side of the housing, and the motion transmission element. In the event that the return leaf spring is attached on both ends inside the housing, respectively one piezoelectric element is expediently rigidly connected to the return leaf spring on both sides of the motion transmission element. In the other above-described variants of the configuration of the actuator for the active haptic feedback, a component of the actuator is attached in the area of the return leaf spring or acts on the area of the return leaf spring in which the return leaf spring is connected to the motion transmission element. The return leaf spring is therefore located in this area between the motion transmission element and the actuator.

The active haptic feedback according to the invention can expediently also comprise the excitation of a balancing weight, as described in principle in WO-A-2017/162586. By exciting the balancing weight in phase opposition to the excitation of the return leaf spring, it is possible to configure the operating device so to speak decoupled, i.e. free of dynamic effects on the environment in which the operating device is arranged. Force transmissions to the instrument panel or the center console, in or on which the operating device is typically arranged in a vehicle, are thus prevented.

In an expedient configuration of the invention it is provided that the at least one motion transmission element is configured as a plate which has side edge portions extending from the mounting edge portion and directed away from the lower side of the operating panel, which side edge portions extend parallel to one another or towards one another as far as the lower end of the motion transmission element. The motion transmission element should extend over a length of between ⅙ and ⅓ (or ½) of the length of the operating panel and be firmly connected to the lower side of the operating panel directly or indirectly across this length. This ensures reliable conversion of the deflection of the operating panel into an offset of the motion transmission element orthogonal to the operating interface, regardless of which operating field of the operating panel is pressed against it.

The design of the motion transmission element as a plate and in particular as a plate with a central opening, so that the motion transmission element substantially resembles the shape of a frame, has the advantage of a lightweight design of the motion transmission element with a rigid and shear-stable design of the motion transmission element. Expediently, a guiding protrusion or similar element can protrude into the frame, i.e. through the central opening, on which the frame is guided in a supporting manner during lateral movement of the motion transmission element.

For example, with a rectilinear upper edge, the frame has an overall rectangular structure or a triangular (isosceles triangle or right-angled triangle) structure or a trapezoidal shape, i.e. it can taper towards its lower edge.

The lower edge at the lower end of the motion transmission element is expediently configured to extend parallel to the mounting edge portion of the motion transmission element.

Instead of a frame or instead of the upper and lower edges of the motion transmission element, it can also be configured as a single rod extending downwards, as a T-shaped or double T-shaped component or as a Π-shaped element with an upper edge part and two side parts extending downwards.

As described above, the operating panel is elastically designed or elastically mounted, which can be done directly or indirectly. The elastic design of the operating panel is an advantage, which, due to the material, is generally given with a material such as plastic, of which the operating panel is advantageously made. The elasticity of the operating panel ensures that it returns to the most plane rest position possible after the operating panel is released following the end of an operation, during which the operating panel bends (slightly) between its two support ends. Because of this deflection of the operating panel, the motion transmission element is advantageous, which ensures a kind of parallel displacement and thus reliable detection of the actuation by a displacement or distance sensor that detects the approach of the motion transmission element or by a force sensor, regardless of the point on the operating panel at which the actuation is carried out manually by pressing against it. In addition, several such sensors are no longer required to detect a valid actuation of the operating panel.

This return movement of the operating panel to the initial or rest position can expediently be supported by an additional return spring, which either acts directly on the operating panel or interacts with it indirectly, for example by engaging the motion transmission element. In the latter case, it is advantageous if the return spring is configured as a leaf spring which protrudes from the motion transmission element at least on one of the two sides thereof, each facing a support end of the operating panel, and comprises a mounting end facing away from the motion transmission element and on which the leaf spring is attached to the housing. The leaf spring is attached to the housing at its mounting end, wherein the motion transmission element and the leaf spring can be moved without change on or inside the housing.

It is advantageous if the plate of the at least one motion transmission element and the leaf spring are formed in one piece and comprise metal, in particular steel and preferably spring steel (or are made thereof), wherein the plate is bent over at the lower edge and a central part of the leaf spring adjoins this bent-over lower edge, from which central part one or respectively one leaf spring arm extends to one or to both sides facing a respective support end of the operating panel. The central part of the leaf spring therefore forms its mounting (fixing) on the motion transmission element, while the mounting end or ends of the leaf spring arm or arms form its mounting on the housing. The leaf spring according to this embodiment thus extends to one side or to both sides of the motion transmission element facing away from each other and parallel to the longitudinal extension of the operating panel. If pressure is applied against the operating panel, the leaf spring arms deform elastically in the direction of displacement of the motion transmission element. It is advantageous if the motion transmission element and the leaf spring or leaf spring arms form a common component. The motion transmission element is substantially orthogonal to the operating panel, while the leaf spring in turn acts orthogonally thereto, which means that the plate or frame of the motion transmission element is bent over at its lower end and this part forms the central part of the leaf spring, from which respectively one leaf spring arm then extends on both sides, each with a mounting end at its free end.

The mounting edge portion of the motion transmission element is expediently connected to the lower side of the operating panel by means of a mounting element.

In a further expedient configuration of the invention, it may be provided that the recess on the front side of the housing has a lateral edge portion connecting the two support edge portions of the housing, on which a first lateral edge portion of the operating panel rests or is attached in a resting manner, and in that the motion transmission element is mounted on a second lateral edge portion of the operating panel opposite the first lateral edge portion of the operating panel, wherein a movement gap is arranged below this second lateral edge portion of the operating panel as far as the recess of the housing. In particular due to the adhesive connection of the operating panel to the housing not only on its support ends, but also on one of its lateral portions, the freedom of deflection of the operating panel on the front side of the housing is impaired. If it is now ensured that the second lateral edge portion of the operating panel is not or at least not rigidly connected to the housing, but if it is ensured that there is a movement gap below this further lateral edge portion of the operating panel towards the housing, which is closed if necessary with a (highly) elastic compressible seal, the operating panel can still be deflected sufficiently freely in its movement when pressing against the operating panel on an operating field. The movement gap in at least partial area of this second lateral edge portion of the operating panel typically points downwards in the installation situation of the operating device if the operating device is arranged on a vertically or substantially vertically extending surface of the instrument panel of a vehicle, as is typically the case. This prevents liquid from accidentally entering the inside of the operating device through the movement gap.

If the operating panel has wider dimensions in particular, for example if it has several rows of adjacent operating fields on its operating interface, it may also be advantageous to provide respectively one motion transmission element on each of the two lateral edge portions mentioned above.

Within the second lateral edge portion of the operating panel, the motion transmission element can be coupled thereto in an expedient manner, allowing this motion transmission element to move either inside the housing or outside at a small distance from the housing. This aforementioned construction results in a space-saving design.

As described above, the operating panel has a touch sensor system that detects which operating field is touched when the operating panel is pressed down. The operating fields are provided with alphanumeric characters or symbols, which are conveniently adapted to be backlit. For this purpose, according to an advantageous configuration of the invention in this respect, the recess on the front side of the housing has a bottom in which light emission openings or transparent areas for backlighting light are formed for backlighting the operating fields of the operating panel, and in that at least one backlighting light source for backlighting light is arranged in the housing. Alternatively, the backlighting light can come from a single or several backlighting light sources and be guided to the operating fields or close to the operating fields by means of light guides. Light wells or reflectors can also be provided in the housing to backlight the operating fields. For this purpose, the front side of the housing needs light transmission openings or areas that are transparent for the backlighting light.

In a further advantageous configuration of the invention, it may be provided that the actuation sensor is a displacement or force sensor or a sensor sensitive to mechanical stresses. In particular, it is expedient if the actuation sensor is configured as an optical displacement sensor for detecting a change in the distance of the lower end of the motion transmission element to the housing, which change occurs when the operating panel is deflected.

The invention is explained in more detail below by means of several exemplary embodiments and with reference to the drawing. In detail, the Figures show:

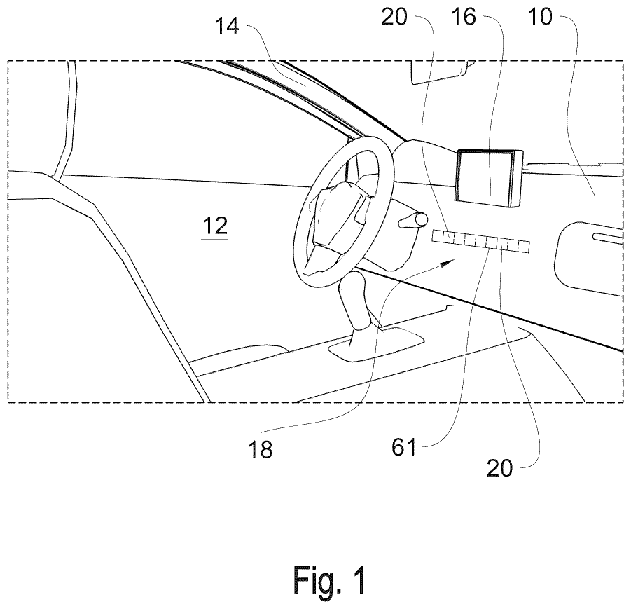

FIG. 1 shows a view of the instrument panel of a vehicle with indicated positioning of an exemplary embodiment of the operating device according to the invention,

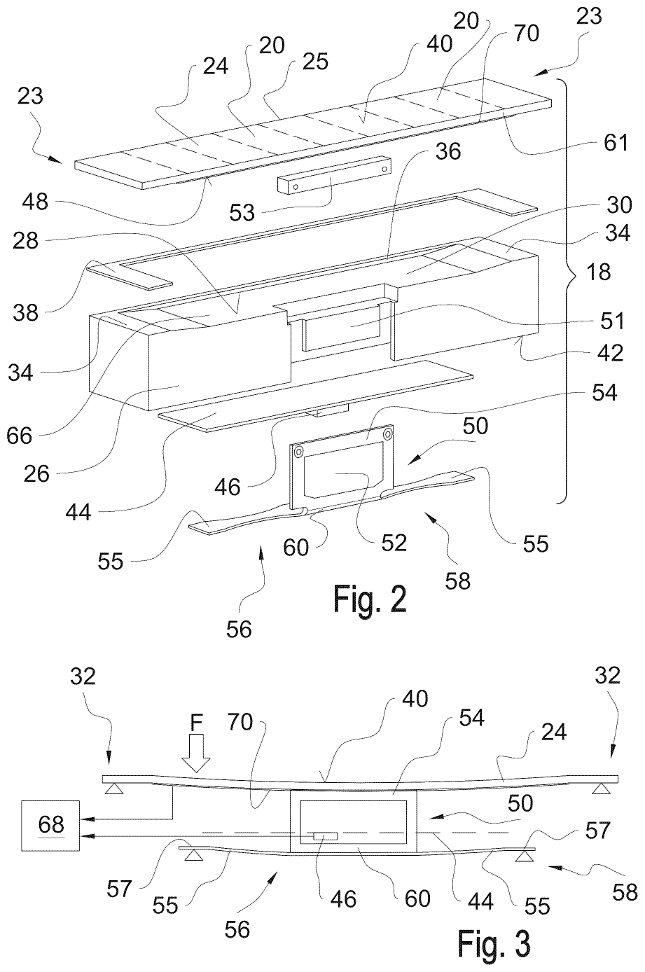

FIG. 2 shows an exploded view of the individual components of the operating device,

FIG. 3 shows a schematic illustration of the operating principle when operating individual operating fields of the operating device,

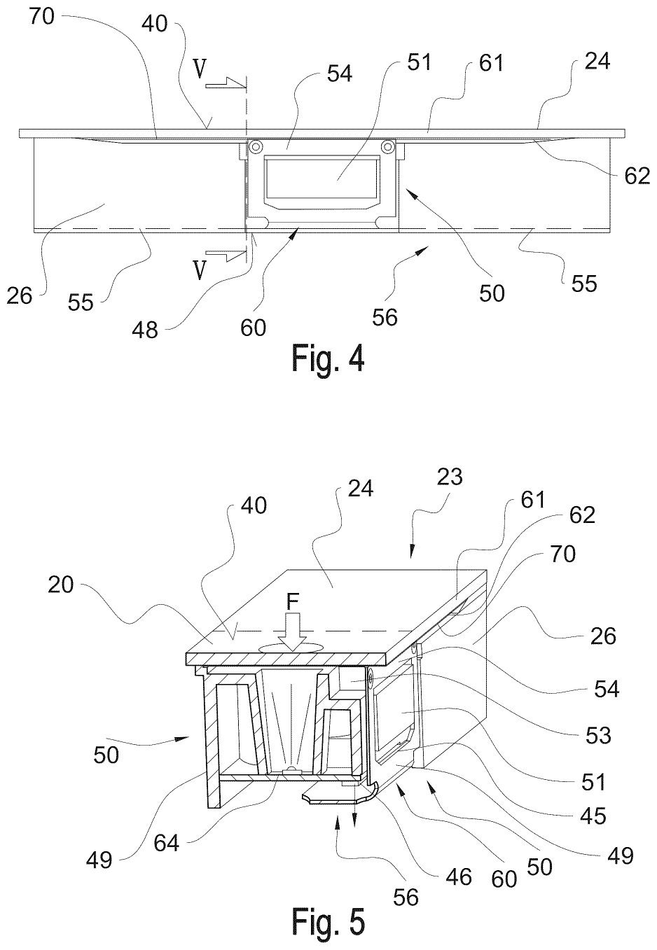

FIG. 4 shows a side view of the operating device,

FIG. 5 shows a perspective bottom/side view of the operating device,

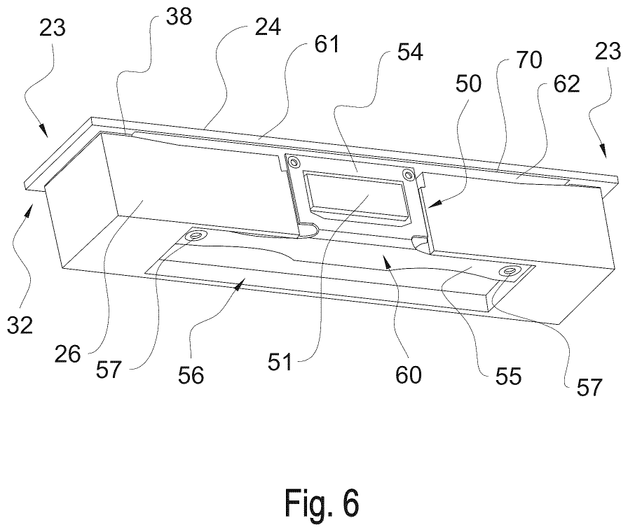

FIG. 6 shows a perspective and sectional view of the operating device,

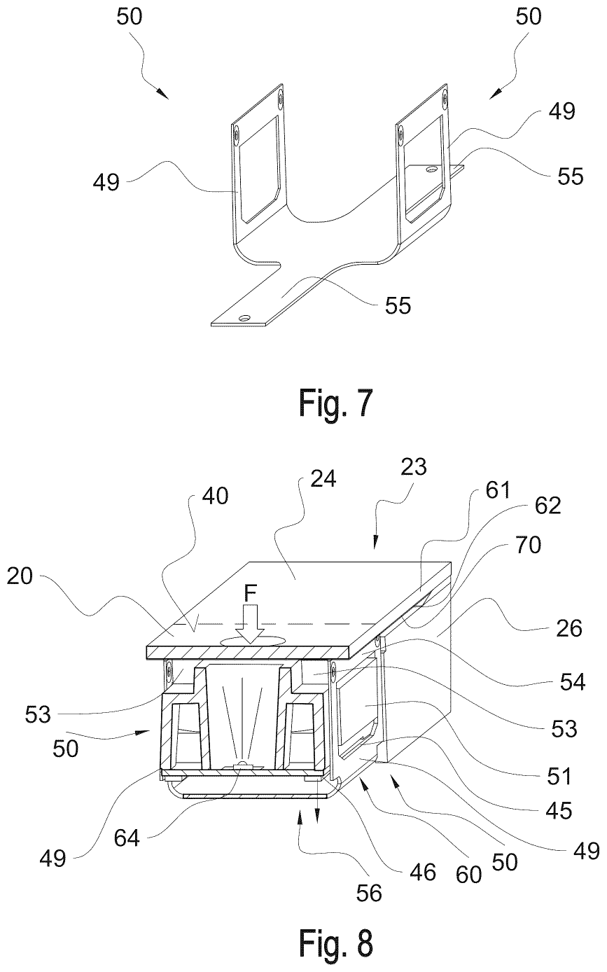

FIG. 7 shows a view of a component with two motion transmission elements and a leaf spring integrally connected thereto,

FIG. 8 shows the installation situation for the component with motion transmission elements shown in FIG. 7,

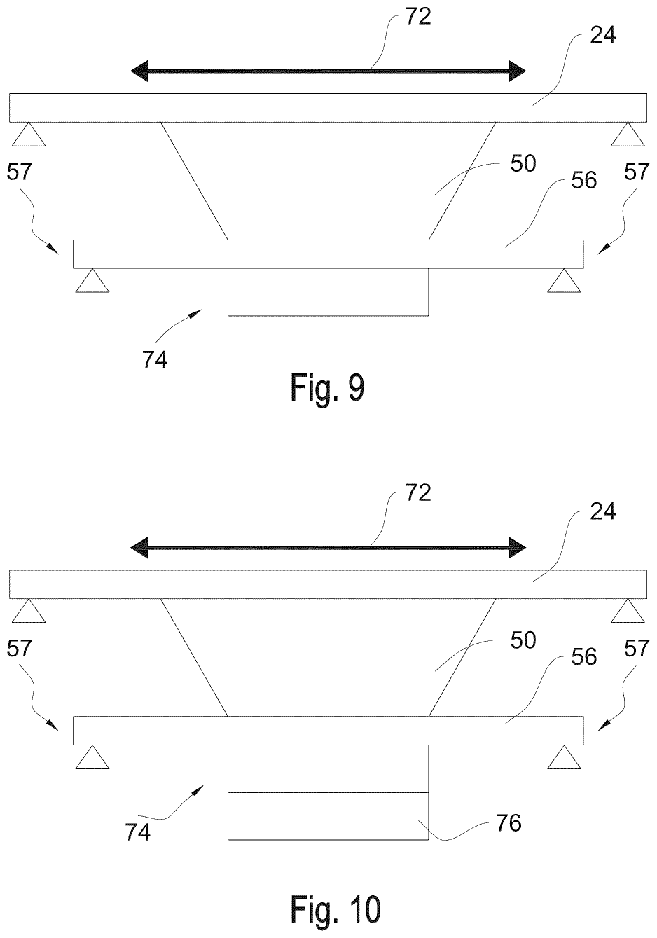

FIG. 9 schematically shows the construction of the two exemplary embodiments of the operating device with a first variant of an actuator for the active haptic feedback,

FIG. 10 schematically shows the construction of the two exemplary embodiments of the operating device with a second variant of an actuator for the active haptic feedback,

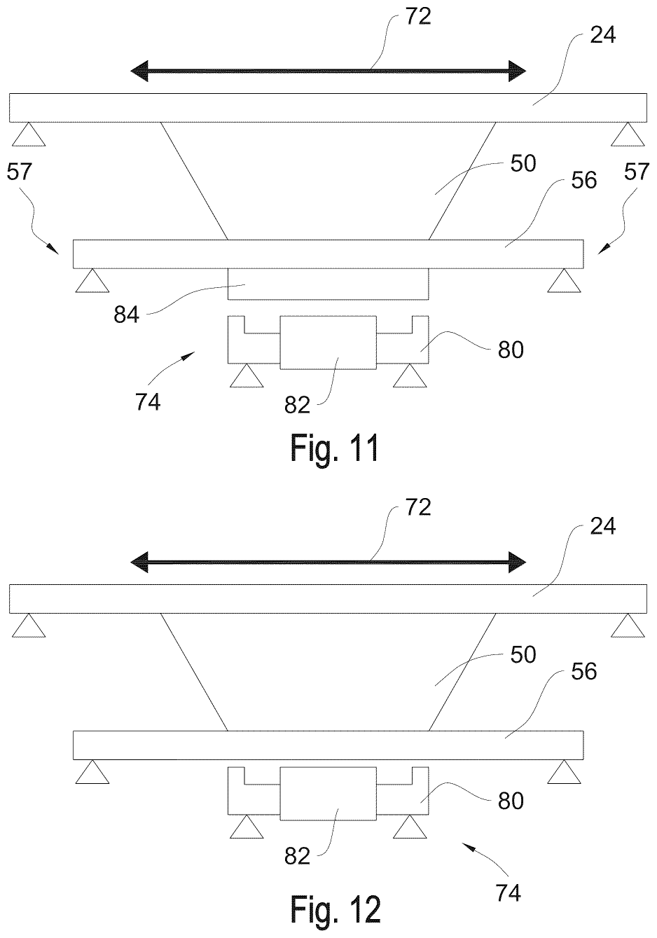

FIG. 11 schematically shows the construction of the two exemplary embodiments of the operating device with a third variant of an actuator for the active haptic feedback,

FIG. 12 schematically shows the construction of the two exemplary embodiments of the operating device with a fourth variant of an actuator for the active haptic feedback,

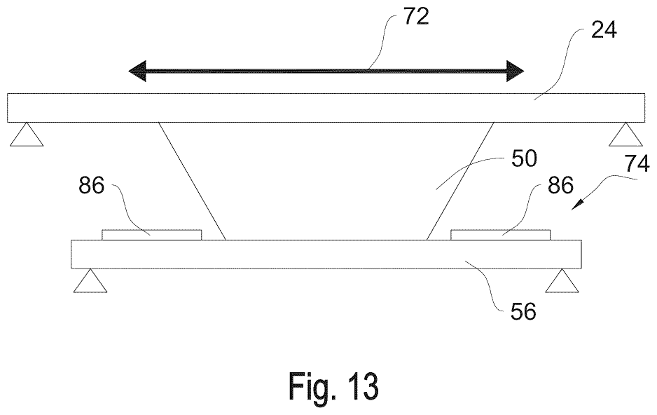

FIGS. 13 to 15 schematically show the construction of the two exemplary embodiments of the operating device with a fifth variant of an actuator for the active haptic feedback,

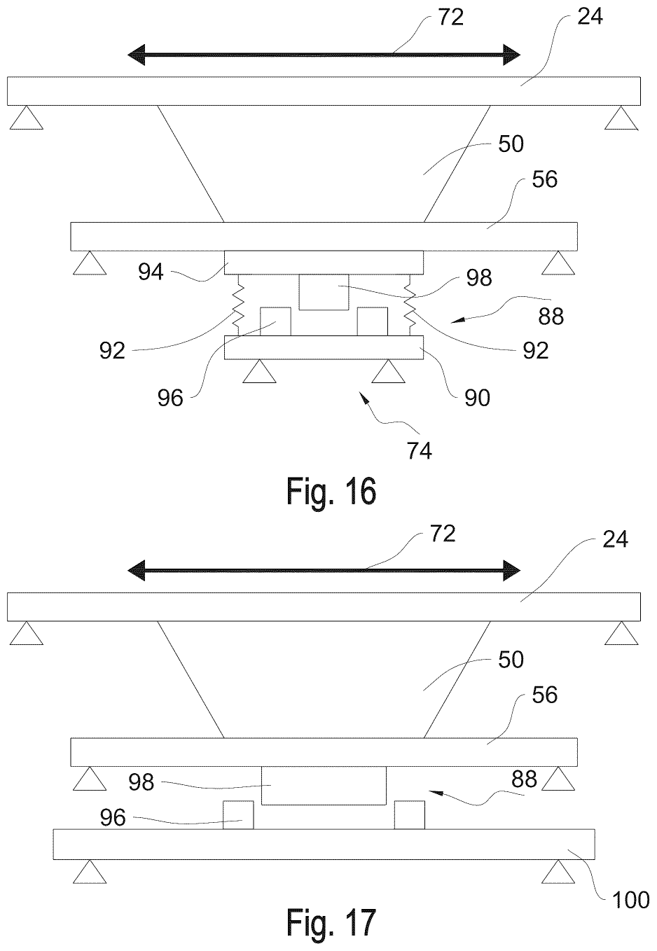

FIG. 16 schematically shows the construction of the two exemplary embodiments of the operating device with a sixth variant of an actuator for the active haptic feedback,

FIG. 17 schematically shows the construction of the two exemplary embodiments of the operating device with a seventh variant of an actuator for the active haptic feedback, and

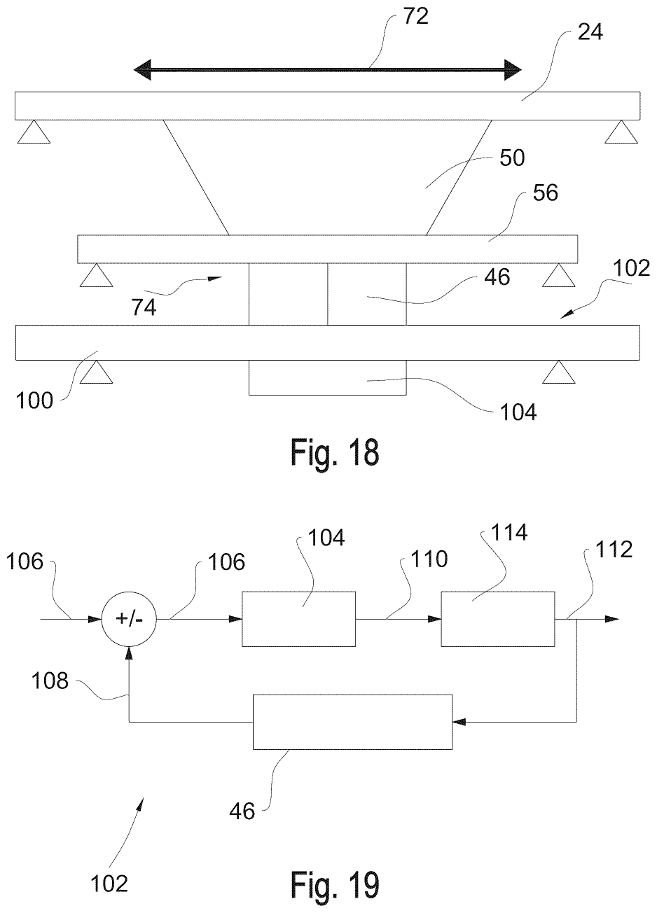

FIGS. 18 and 19 schematically show the construction and the block diagram of a feedback control system for the active haptic feedback.

FIG. 1 shows a perspective view of the instrument panel 10 in the interior 12 of a vehicle 14, which in this exemplary embodiment is provided with a display 16 and an exemplary embodiment of an operating device 18 according to the invention, which is an operating bar with a closed surface and a plurality of operating fields 20 (in this case five such operating fields) indicated by dashed lines in FIG. 1. The special feature of the operating device 18 is to be seen in the fact that the operating interface is formed by a flexible, elastic, strip-shaped operating panel 24, which can be pressed down on contact with any of the operating fields 20 and bends slightly, wherein a single sensor is sufficient to detect a valid actuation of the operating device 18.

The structure of the operating device 18 is shown in FIGS. 2 to 6.

As already mentioned above, the operating device 18 has an elongated, strip-shaped operating panel 24 on which, which is not shown in the figures, alphanumeric characters or symbols are typically depicted to mark the functions to be triggered by the individual operating fields. The flexible operating panel 24, made of plastic for example, rests on a housing 26, which has a front side 28, on the support ends 23 facing away from each other in the longitudinal direction and on one of its longitudinal edge portions 25. On the front side 28, there is a comparatively flat indentation or depression or generally recess 30 on the housing 26, which has support edge portions 34 on the two opposite narrow edges 32 of the front side 28. A lateral edge portion 36 is located along a lateral side of the housing 26 on its front side. The lateral side opposite this lateral edge portion 36 does not have such an edge portion projecting upwards, so that the recess 30 is open towards this lateral side in this respect and can be protected against the ingress of dust particles, for example, by a compressible sealing strip.

A double-sided adhesive fixing tape 38, which is C-shaped so to speak, rests on the two aforementioned support edge portions 34 and the lateral edge portion 36. Finally, the operating panel 24 rests on this fixing strip 38, which is thus firmly connected to the housing 26 on its front side 28 on three sides or edges, namely on the edges of the support ends 23 and on one of the two longitudinal edge portions 25. The recess 30 below the operating panel 24 now allows it to deflect slightly when pressure is exerted on the upper side of the operating panel 24, which forms the operating interface 40. However, the adhesive connection between the operating panel 24 and the housing 26 can also be provided only at the support ends 23 and the support edge portions 34.

On the lower side 42 of the housing 26 there is a carrier plate 44 for various electrical, electronic and optical components such as backlighting light sources, as shown in FIG. 6. There is also an actuation sensor 46 on the carrier plate 44, which detects an actuation (deflection) of the operating panel 24.

In order to be able to detect the minimum deflection required for valid actuation, irrespective of which of the operating fields 20 the operating panel 24 is pressed against, a motion transmission element 50 is mechanically connected to the lower side 48 of the operating panel 24, which extends away from the operating panel 24 orthogonally to the lower side 48 of the latter. In this exemplary embodiment, this motion transmission element 50 is configured as a metal frame 49, i.e. it has a plate with an opening 52. The upper mounting edge portion 54 of the motion transmission element 50 is rectilinear and extends in the longitudinal extension direction of the operating panel 24. A mounting element 53, which is part of the mounting edge portion 54, is firmly mounted to the lower side 48 of the operating panel 24. The opening 52 in the plate of the motion transmission element 50 forms the frame 49, into which a guiding protrusion 51 protrudes so to speak as a linear guiding support for the motion transmission element 50 when the frame is moved.

As can be seen in FIG. 2, a two-armed leaf spring 56 extends below the motion transmission element 50 in this exemplary embodiment as an exemplary embodiment of a return spring 58, which moves the return movement of the elastic operating panel 24 back to the initial position after being pressed down and after the pressing-down force has been released. The return spring 58 is arranged on the lower end 60 of the motion transmission element 50 and is preferably connected in one piece to the metal frame of the motion transmission element 50, so that the leaf spring 56 and the motion transmission element 50 are configured as a one-piece punched part which, after the punching process, is given its shape shown in FIG. 2 by bending along the lower end 60.

A side view of the operating device 18 with a view of the motion transmission element 50 is shown in FIG. 4. As can also be seen from FIGS. 2, 5 and 6, the motion transmission element 50 is located below that longitudinal edge portion 61 of the operating panel 24 below which no lateral edge portion extends on the front side 28 of the housing 26, so that a movement gap 62 is formed there between the operating panel and the recess 30 on the front side 28 of the housing 26.

The kinematics of the operating device 18 are shown in FIG. 3. The leaf spring 56 and the operating panel 24 are mounted on fixed bearings at their respective opposite ends (indicated by the triangles in FIG. 3). The two (mounting) ends 57 of the two arms 55 of the leaf spring 56 are attached to the lower side 42 of the housing 26, as can be seen in FIG. 5, for example, thus forming the two lower bearings in FIG. 3. The operating panel 24 is supported on its support ends 23 on the housing not shown in FIG. 3, thus forming the two upper bearings shown in FIG. 3.

If a pressing force is now exerted on the operating interface 40 of the operating panel 24, as shown in FIG. 3 by arrow F, the operating panel 24 moves downwards and deflects in doing so. This deflection is transmitted downwards in the area of the motion transmission element 50, which preferably extends symmetrically to the center line of the operating panel 24 between its support ends 23, whereby the leaf spring 56 or generally the return spring 58 is tensioned. When the pressure force is released/removed, the return spring 58 and the operating panel 24 move back to their initial positions.

The advantage of this construction, i.e. the advantage of the arrangement and construction of the motion transmission element 50, is that it moves downwards reliably and substantially consistently when pressing against the operating panel 24 at any point. The actuation sensor 46, which is configured for example as an optical distance sensor, can be used to detect the movement offset of the motion transmission element 50, which it experiences when pressed against the operating panel 24. For this purpose, the actuation sensor 46 is arranged, for example, on the carrier plate 44 and “looks” from there onto the bent central portion of the lower end 60 of the motion transmission element 50 (see FIG. 6). The arrow in FIG. 6 indicates that the lower end 60 of the motion transmission element 50 moves downwards when pressure is exerted on the operating panel 24 from above, as indicated by the further arrow F in FIG. 6. Since the position of the actuation sensor 46 relative to the housing 26 remains unchanged, a change in distance can therefore be detected optically, capacitively, inductively or the like, for example.

In FIG. 6 it is also indicated that one or more backlighting light sources 64 are arranged inside the housing, namely on the carrier plate 44, the light of which is directed for example by light guides or reflectors from below towards the lower side 48 of the operating panel 24, wherein the bottom 66 of the recess 30 of the housing 26 has transparent zones or even openings for the light, so that the backlighting light passes out of the housing 26 and from below towards the operating panel 24, where the symbols or alphanumeric characters of the operating panels 20 are backlit. For this purpose, the lower side 48 of the operating panel 24 may have an opaque coating which has freely cut symbols or alphanumeric characters, typically freely cut by laser, which then become more clearly visible by backlighting.

A control and evaluation unit 68, shown schematically in FIG. 3, is used to evaluate whether manual actuation of the operating panel 24 means a valid command input. This control and evaluation unit 68, which operates electronically and has, for example, I/O ports, memories and a microprocessor, receives signals from the actuation sensor 46 and from a touch sensor system 70 on the lower side of the control panel 24, for example. Said touch sensor system can operate capacitively, resistively, optically or the like. The touch sensor system 70 therefore detects the position at which the operating interface 40 of the operating panel 24 is pressed against it. The actuation sensor 46 outputs a measurement signal that is representative of the change in its distance from the mounting end 60 of the motion transmission element 50. Once a predetermined minimum distance change is reached, a valid manual operation of the operating interface 40 of the operating device 18 is recognized to then trigger the action associated with the touched operating field 20 of the operating panel 24.

As described above, the movement gap 62 is located below the longitudinal edge portion 61 of the operating panel 24. If the operating device 18, as shown in FIG. 1, is aligned in such a way that this movement gap 62 is located at the lower edge of the operating device 18 in the installed state, the ingress of liquids, for example, into the operating device 18 is reliably prevented. The closed operating interface 40 also contributes to this.

The previous description of the exemplary embodiment of the invention relates to the use of a motion transmission element 50. As already described above, depending on the size of the operating panel 24 of the operating device 18, it may be advantageous if two motion transmission elements 50 are provided. The metal component that can be used in this respect, with two motion transmission elements 50 each in the form of a frame 49 and the leaf spring 56 integrally connected to both, is shown in FIG. 7.

The installation situation of this component is shown in FIG. 8. The indentation-shaped recess 30 on the front side 28 of the housing 26 now has a movement gap 62 on its two lateral edge portions 36 extending in parallel. There is a guiding projection 51 on each of the two longitudinal side surfaces of the housing 26. The two frames 49 are each connected to a mounting element 53 on the lower side 42 of the operating panel 24.

In FIGS. 9 to 18, the structure of the operating device 18 described above is shown in a highly schematized form in that only those elements are shown which are decisive for the active haptic feedback according to the invention.

In FIG. 9, the double arrow 72 indicates the area of the operating fields 20 on the operating panel 24. The motion transmission element 50 is represented by the trapezoidal element and connects the operating plate 24 with the return leaf spring 56. The return leaf spring 56 is mounted inside the housing on its two mounting ends 57.

An actuator 74, which is optionally (see FIG. 10) supported in the housing (see indicated at 76 in FIG. 10), is attached to the return leaf spring 56 or is operatively connected thereto.

In FIGS. 11 and 12, two exemplary embodiments are shown as two variants of the actuator 74, in which the actuator 74 is designed as a tie rod magnet 78 (or also tie rod electromagnet). In the exemplary embodiment of FIG. 11, the tie rod magnet 78 has a stator 80 with a stator coil 82 and a ferromagnetic armature 84. The armature 84 is connected to the return leaf spring 56, preferably on its lower side in that (in particular central) area in which the motion transmission element 50 is connected to the upper side of the return leaf spring 56. The stator 80 is mounted in the housing. In the exemplary embodiment according to FIG. 12, the armature of the tie rod magnet 78 is formed by the leaf spring 56 itself, which has ferromagnetic properties for this purpose.

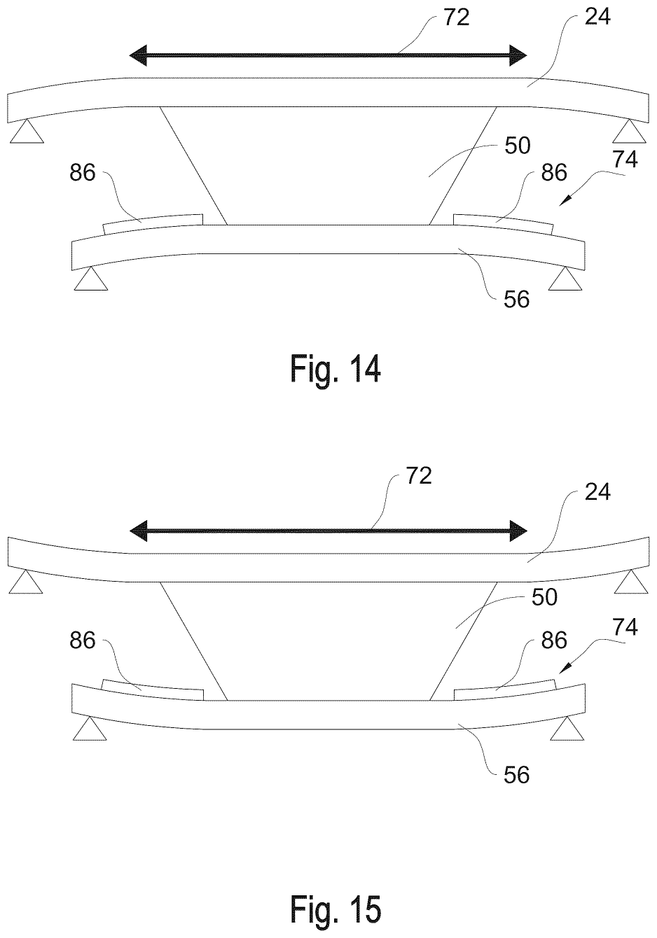

In the exemplary embodiment of FIGS. 13 to 15, two piezoelectric elements 86 are used as actuator 74, which are attached to the return leaf spring 56 on both sides of the connection between the motion transmission element 50 and the return leaf spring 56 in a shear-resistant manner. FIGS. 14 and 15 show how the operating panel 24 and the return leaf spring 56 move/deform depending on the polarity of the electrical voltage on the piezoelectric elements.

In FIG. 16, the actuator 74 is configured as a plunger coil actuator 88. The plunger coil actuator 88 has a base plate 90 on which an actuator element 94 is elastically mounted by springs 92. A coil 96 is located on or at the base plate 90, in which a permanent magnet element 98 is at least partially immersed, which in turn is connected to the actuator element 94. In a known manner, the permanent magnet element 98 can now be moved forwards and backwards by applying an electrical (in particular) alternating voltage, which is transmitted via the actuator element 94 to the return leaf spring 56 and from this, as in all exemplary embodiments described above and below, to the operating panel 24.

In the exemplary embodiment of the plunger coil actuator 88 of FIG. 17, the actuator element 94 is omitted. It is replaced by the return leaf spring 56, to which the permanent magnet element 98 is attached. In addition, the base plate 90 is replaced by a printed circuit board 100 to which the coil 96 is attached.

In FIGS. 18 and 19, a feedback control system 102 for the actuator 74 is shown schematically and as a block diagram for the purpose of controlling the deflection of the operating panel 24 during the pulse-or vibration-like excitation for the active haptic feedback. A control circuit 104 receives at its input the difference between a target deflection 106 and the actual deflection 108, which is detected by a sensor 46 (e.g. force or displacement sensor), and outputs an output signal 110. The circuit 102 outputs a control signal 112 to the actuator 74, whereupon the dynamic system 114 comprising the movable components of the actuator 74 and the return leaf spring 56, motion transmission element 50 and operating panel 24 responds so that the predetermined target deflection 106 is set.

### LIST OF REFERENCE NUMERALS

10 instrument panel
12 interior
14 vehicle
16 display
18 operating device
20 operating fields
23 support ends of the operating panel
24 operating panel
25 longitudinal edge portion of the panel
26 housing
28 front side
30 recess
32 narrow edges
34 support edge portion
36 lateral edge portion
38 fixing tape
40 operating interface on the top of the operating panel
42 lower side of the operating panel
44 carrier plate
46 actuation sensor
48 lower side of housing
49 frame
50 motion transmission element
51 guiding protrusion
52 opening
53 mounting element
54 mounting edge portion
55 leaf spring arms
56 leaf spring
57 mounting ends of the leaf spring
58 return spring
60 lower end of the motion transmission element
61 longitudinal edge portion
62 movement gap
64 backlighting light sources
66 bottom of the recess on the front side of the housing
68 control and evaluation unit
70 touch sensor system
72 area of the operating fields
74 actuator
76 support of the actuator
78 tie rod magnet
80 stator
82 stator coil
84 armature
86 piezoelectric element
88 plunger coil actuator
90 base plate
92 springs
94 actuator element
96 coil
98 permanent magnet element
100 printed circuit board
102 feedback control system
104 control circuit
106 target deflection
108 actual deflection
110 output signal of the control circuit
112 control signal for the actuator
114 dynamic system

1. An operating device for a vehicle, comprising
a housing having a front side with a recess extending between two opposing support edge portions on the front side of the housing,
an elastic and/or directly or indirectly elastically mounted operating panel comprising two opposite support ends for support on the two support edge portions, on which the operating panel is mounted and/or attached to the housing, and covering the recess,
wherein the operating panel is adapted to be reversibly pressed down from a rest position into an actuation position and has an operating surface with operating fields,
a position detection sensor system for detecting the operating field of the operating surface of the operating panel which is contacted manually or by an object when being pressed down,
a return leaf spring arranged in the housing to support the movement of the depressed operating panel back to its rest position,
at least one actuation sensor for detecting when the operating panel assumes the actuation position,
at least one motion transmission element for transmitting the depression movement of the operating panel into a deflection of the return leaf spring,
wherein the at least one motion transmission element is arranged between the operating panel and the return leaf spring and has two opposite, rectilinear end portions, of which the first end portion is connected to the operating panel and the opposite second end portion is connected to the return leaf spring,
a control and evaluation unit which receives signals from the position detection sensor system and the at least one actuation sensor and, when a valid actuation of the operating panel is detected by transferring the operating panel into its actuation position by touching an operating field of the operating surface, outputs an output signal for further processing thereof to trigger an action associated with the relevant operating field, and
an actuator for pulse-or vibration-like excitation of the operating panel when the latter is validly actuated,
wherein the actuator is adapted to be controlled by an output signal emitted by the control and evaluation unit when a valid actuation is detected, and
wherein the actuator interacts with or acts on the return leaf spring to move the latter in order to excite the operating panel in a pulse-or vibration-like manner.

2. The operating device according to claim 1, wherein the actuator is configured as a tie rod magnet with a stator mounted in the housing and provided with a coil and a ferromagnetic armature and in that the armature is connected to the return leaf spring for pulse-or vibration-like excitation of the latter.

3. The operating device according to claim 1, wherein the actuator is configured as a tie rod magnet with a ferromagnetic armature attached in the housing and a stator provided with a coil, and in that the stator is connected to the return leaf spring for pulse-or vibration-like excitation of the latter.

4. The operating device according to claim 1, wherein the actuator is configured as a tie rod magnet with a stator mounted in the housing and provided with a coil and a ferromagnetic armature, and in that the return leaf spring forms the ferromagnetic armature of the tied rod magnet.

5. The operating device according to claim 1, wherein the actuator is configured as a plunger coil actuator comprising a base plate which is attached inside the housing and on which a coil is located, a resilient actuator element which is mounted on the base plate and is arranged at a distance from the base plate, and a permanent magnet element which is arranged on the actuator element and is at least partially immersed in the coil and in that the actuator element is connected to the return leaf spring for pulse-or vibration-like excitation of the latter.

6. The operating device according to claim 1, wherein the actuator is configured as a plunger coil actuator comprising a base plate which is attached inside the housing and on which or at which a coil is mounted, and a permanent magnet element which is at least partially immersed in the coil, and in that the permanent magnet element is connected to the return leaf spring for pulse-or vibration-like excitation of the latter.

7. The operating device according to claim 5, wherein the base plate is a printed circuit board, and in that the coil is attached to the printed circuit board.

8. The operating device according to claim 1, wherein the actuator comprises at least one plate-shaped or strip-shaped piezoelectric element with two main surfaces and with two connection elements, wherein the at least one piezoelectric element contracts or expands when an electrical voltage is applied to the connection elements, depending on the polarity, and in that the at least one piezoelectric element rests with one of its main surfaces against the return leaf spring for pulse-or vibration-like excitation and is rigidly connected thereto.

9. The operating device according to claim 1, wherein the control and evaluation unit comprises a controller for controlling the deflection of the operating panel in the event of pulse-or vibration-like excitation thereof as a result of activation of the actuator, wherein the controller receives at its input a differential signal from a signal representing a target deflection of the operating panel and a signal representing the current extent of the deflection of the operating panel and outputs at its output a control signal for the actuator for controlling the deflection of the operating panel in accordance with the target deflection.

10. The operating unit according to claim 1, wherein the return leaf spring has two ends, the first end of which is attached in the housing, wherein the return leaf spring is arranged to protrude from this first end, and in that the second edge portion of the at least one motion transmission element is connected to the return leaf spring in the region between its first end and its second end or to the second end of the return leaf spring.

11. The operating unit according to claim 1, wherein the return leaf spring has two ends, both of which are attached in the housing, and in that the second edge portion of the at least one motion transmission element is connected to the return leaf spring in the region between its two ends.

12. The operating unit according to claim 10 wherein respectively one piezoelectric element is rigidly connected to the return leaf spring on both sides of the at least one motion transmission element.

13. The operating device according to claim 1, wherein the at least one motion transmission element is configured as a plate which has side edge portions extending from the mounting edge portion and directed away from the lower side of the operating panel, which side edge portions extend parallel to one another or towards one another as far as the lower end of the at least one motion transmission element.

14. The operating device according to claim 13, wherein the lower end of the at least one motion transmission element comprises an edge portion parallel to the mounting edge portion.

15. The operating device according to claim 13, wherein the plate of the at least one motion transmission element comprises an opening and that the mounting edge portion, the side edge portions and the lower end of the at least one motion transmission element form a frame.

16. The operating device according to claim 1, characterized by a return spring cooperating directly or indirectly with the operating panel to support the return movement of the operating panel after manual depression thereof.

17. The operating device according to claim 16, wherein the return spring is configured as a leaf spring which protrudes from the at least one motion transmission element at least on one of the two sides thereof, each facing a support end of the operating panel, and comprises a mounting end facing away from the at least one motion transmission element and on which the leaf spring is attached to the housing.

18. The operating device according to claim 17, wherein the leaf spring protrudes on both sides of the at least one motion transmission element respectively towards one support end of the operating plate and has two mounting ends attached to the housing and arranged offset in height relative to the support elements.

19. The operating device according to claim 18, wherein the plate of the at least one motion transmission element and the leaf spring are formed in one piece and comprise metal, in particular steel, wherein the plate is bent over at the lower edge and a central part of the leaf spring adjoins this bent-over lower edge, from which central part one or respectively one leaf spring arm extends to one or to both sides facing a respective mounting end of the housing.

20. The operating device according to claim 1, characterized by a mounting element attached to the lower side of the operating panel, to which the mounting edge portion of the at least one motion transmission element is attached.

21. The operating device according to claim 1, wherein the recess on the front side of the housing has a lateral edge portion connecting the two support edge portions of the housing, on which a first lateral edge portion of the operating panel rests or is attached in a resting manner, and in that the motion transmission element is mounted on a second lateral edge portion of the operating panel opposite the first lateral edge portion of the operating panel, wherein a movement gap is arranged below this second lateral edge portion of the operating panel as far as the recess of the housing.

22. The operating device according to claim 1, wherein the recess on the front side of the housing has a bottom in which light emission openings or transparent areas for backlighting light are formed for backlighting the operating fields of the operating panel, and in that at least one backlighting light source for backlighting light is arranged in the housing.

23. The operating device according to claim 1, wherein the actuation sensor is a displacement or force sensor or a sensor sensitive to mechanical stresses.

24. The operating device according to claim 1, wherein the actuation sensor is configured as an optical displacement sensor for detecting a change in the distance of the lower end of the at least one motion transmission element to the housing and, in particular, to the lower side of the housing, which change occurs when the operating panel is deflected.

25. The operating device according to claim 1, wherein the mounting edge portion of the at least one motion transmission element has a length which is between ⅙ and ⅓ of the longitudinal extension of the operating panel between the support ends thereof and/or in that the mounting edge portion of the at least one motion transmission element is arranged symmetrically with respect to the center of the operating panel between the support ends thereof.

26. The operating device according to claim 1, wherein the operating panel comprises a material transparent to backlighting light.

27. The operating device according to claim 1, wherein the operating panel is strip-shaped, and in that the operating fields are arranged successively on the top of the operating panel in the longitudinal extension thereof.
